(19) United States
(12) Patent Application Publication
(10) Pub. No.: US 2004/0157456 A1
(43) Pub. Date: Aug. 12, 2004

(54) Surface defect elimination using directed beam method

(76) Inventors: Lindsey H. Hall, Plano, TX (US); Satyavolu S. Papa Rao, Garland, TX (US); Sanjeev Aggarwal, Plano, TX (US); Asad M. Haider, Plano, TX (US)

Correspondence Address: TEXAS INSTRUMENTS INCORPORATED, P O BOX 655474, M/S 3999, DALLAS, TX, 75265

(21) Appl. No.: 10/752,638

(22) Filed: Jan. 6, 2004

Related U.S. Application Data
(60) Provisional application No. 60/446,147, filed on Feb. 10, 2003.

(51) Int. Cl. H01L 21/302; H01L 21/461

(52) U.S. Cl. 438/692

(57) ABSTRACT

A gas cluster ion beam (GCIB) (40) is formed in an ion beam tool (20). The position of a particle (30) on the wafer surface is determined and the GCIB is directed unto the particle (30) removing the particle from the surface on which it rests.

### FIELD OF THE INVENTION

The invention is generally related to the field of integrated circuit manufacture and more specifically to a method of removing particle and residue defects using a directed beam.

### BACKGROUND OF THE INVENTION

In an integrated circuit manufacturing process the yield is determined by the number of fully functional integrated circuits that formed on each wafer or lot of wafers. The functionality of an individual integrated circuit is to a large extent determined by the functionality of each individual electronic device and interconnects. Although many factors can affect the functionality of an integrated circuit one of the most important is the presence of particle defects that are introduced during manufacture. Particle defects can result in the nonfunctioning of the individual electronic devices that comprise the integrated circuit thereby leading to circuit failure. As the size of the individual electronic devices that comprise the integrated circuit is reduced particles of very small sizes (˜0.2 μm) are becoming yield limiting defects.

Many different processes are used in the manufacture of an integrated circuit. Each of these processes will introduce varying numbers of defects that can be removed using various techniques. The increasing use of chemical mechanical polishing however has lead to the introduction of organic particle defects that are very difficult to remove using existing methods. This is especially true after copper chemical mechanical polishing where the combination of the exposed copper surface and the organic solutions used in the process results in particle defects that are particularly difficult to remove. Some of the reasons for this difficulty are the limited exposure of the integrated circuit at this particular stage of its manufacture to water and heat and the hydrophobicity differences between the various exposed surfaces on the wafer. There is therefore a need for an improved method to remove particle defects. The instant invention addresses this need.

### SUMMARY OF THE INVENTION

A method for removing a particle from the surface of a semiconductor wafer is described. A gas cluster ion beam (GCIB) comprising 50 to 5000 entities is formed and emitted from an ion beam tool at energies from 1 KeV to about 50 KeV. The position of a particle on a semiconductor wafer is determined and the GCIB is directed unto the particle. The incident entities of the GCIB will remove the particle from the surface of the semiconductor wafer.

A major advantage of the instant invention is that the GCIB will remove the particle without damaging the underlying surface of the semiconductor wafer. This and other technical advantages of the instant invention will be readily apparent to one skilled in the art from the following FIGUREs, description, and claims.

### BRIEF DESCRIPTION OF THE DRAWINGS

In the drawings:

FIG. 1(a) and FIG. 1(b) are diagrams illustrating an embodiment of the instant invention.

FIG. 2 is a cross-section diagram showing a defect particle according to the instant invention.

FIG. 3 is a diagram showing the position of a particle on a semiconductor wafer.

Corresponding numerals and symbols in the different figures refer to corresponding parts unless otherwise indicated.

### DETAILED DESCRIPTION OF THE INVENTION

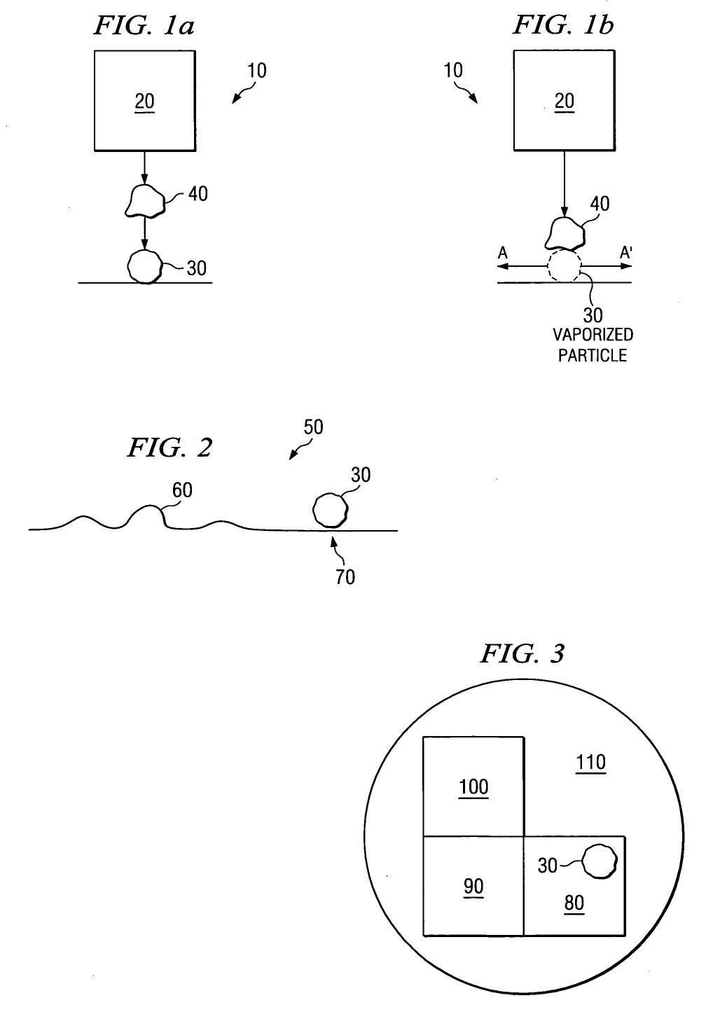

Copper metallization is important for high performance integrated circuits. In forming copper metal lines a trench is formed in a dielectric layer that overlies a silicon wafer. Copper is used to fill the trench and the excess copper is removed using chemical mechanical polishing (CMP). In the CMP process an abrasive pad is applied to the copper layer and the excess copper removed. The polished copper surface will corrode if left in the ambient of the fabrication facility and therefore following the CMP process a passivation solution of benzotriazole (BTA) is applied to the copper surface. This organic passivant will form a thin organic film on the copper surface that inhibits corrosion. CMP is inherently a “dirty” process and invariably particles are left on the polished surface. Following copper CMP processes the polished surface is cleaned to remove particles while leaving at least a thin remaining layer of BTA. During the BTA process it is likely that the BTA will form particles in the form of thick residue on the wafer. As described above these particles, if not removed, can lead to inoperable integrated circuits. Further processing of the integrated circuit requires that an etch stop layer be formed on the copper surface before the subsequent formation of other layers of copper metallization. The typical etch stop layer comprises silicon nitride and prior to the formation of the silicon nitride layer the remaining BTA film is removed using a plasma treatment. This plasma treatment however seldom removes all the BTA from the copper surface (having particular difficulty with any remaining thick residue) and the remaining BTA forms particles on the copper surface. The particles formed during the BTA removal process are organic in nature and are particularly difficult to remove using existing cleaning methods. Such a particle 30 is shown in FIG. 1A lying on the surface of a copper layer 10. The copper layer 10 is formed as part of an integrated circuit that is formed on a semiconductor wafer. Other features that are present on the integrated circuit and the semiconductor wafer have been omitted from the Figures for clarity. It should be noted that while the instant invention will be described with reference to an organic particle on a copper layer the instant invention is applicable to any particle found on any surface.

In an embodiment of the instant invention a gas cluster ion beam (GCIB) is used to selectively remove the particle 30 shown in FIG. 1(a). A GCIB comprises approximately 50 to 5000 entities grouped together in a cluster. The cluster of entities has an overall net charge but not all the entities that comprise the cluster are charged. The entities that comprise the GCIB can be atoms, molecules, or any other suitable entity. Argon, nitrogen, hydrogen, CF₄, and other suitable species can be used to form the GCIB. Shown in FIG. 1(a) is a GCIB 40 being directed towards the particle 30. As shown in FIG. 3 the particle 30 is on an integrated circuit 80 that is being formed on a semiconductor wafer 110. Other integrated circuits 90, 100 are also shown in the Figure. The position of the particle 30 on the integrated circuit 80 and on the semiconductor wafer 110 can be determined using existing particle detection methods. Having determined the position of the particle 30 on the wafer 110, the GCIB can then be directed towards the particle to selectively remove the particle from the surface. In addition the GCIB can be rastered to cover known regions of the semiconductor wafer or in some instances the entire semiconductor wafer. As shown in FIG. 1(a) the GCIB 40 is formed and emitted from a GCIB tool 20 at energies from 1 KeV to about 50 KeV although other energies can be used. Commercially available tools such as the Epion Smoother System 400 can be used to form the GCIB. For the embodiment where copper is the underlying layer 10, an argon GCIB is used to remove particles without damaging the underlying copper layer 10. For other embodiments comprising different types of particles, species such as nitrogen, hydrogen, CF₄ can be used to form the GCIB.

As shown in FIG. 1(b) the particle 30 is vaporized by the GCIB 40 on impact and therefore removed from the surface. It is believed that the GCIB dissipates most of its energy in a lateral direction AA′ upon impact with the surface as shown in FIG. 1(b). If the GCIB is incident on the surface of the copper layer 10, this lateral dissipation of energy will not harm the copper surface. If the GCIB is incident on the particle 30 however, the energy of the incident GCIB transfers enough energy to the particle to vaporize the particle or at least knock it from the surface. In either case the particle is removed from the copper surface.

It is important in the instant invention to distinguish what is meant by a particle compared to some other surface feature and this distinction is shown in FIG. 2. In the Figure, a particle 30 is shown lying on the surface of a layer 50. In the instant invention a particle is defined as having an interface between itself and the underlying surface. Such an interface 70 is shown in FIG. 2. A surface feature 60 is also shown in FIG. 2. The surface feature does not have an interface with the underlying layer 50 and is contiguous with the underlying layer 50. It should be noted that the above meaning of particle in the instant invention is meant to include residue as well as any other substance on the surface.

While this invention has been described with reference to illustrative embodiments, this description is not intended to be construed in a limiting sense. For example, the instant invention has been described with reference to an organic particle on a copper layer. The instant invention is not limited to this embodiment however and is applicable to all particles formed during integrated circuit manufacture. Various modifications and combinations of the illustrative embodiments, as well as other embodiments of the invention, will be apparent to persons skilled in the art upon reference to the description. It is therefore intended that the appended claims encompass any such modifications or embodiments.

We claim:

1. A method for removing a particle from a semiconductor, comprising:
providing a semiconductor wafer comprising a particle;
forming a gas cluster ion beam; and
directing said gas cluster ion beam unto said particle thereby removing said particle.

2. The method of claim 1 wherein said gas cluster ion beam comprises 50 to 5000 entities.

3. The method of claim 2 wherein said gas cluster ion beam is emitted from a GCIB tool at energies from 1 KeV to about 50 KeV.

4. The method of claim 3 wherein the entities comprising said gas cluster ion beam are selected from a group consisting of argon, CF₄, hydrogen, and nitrogen.

5. The method of claim 4 further comprising the step of determining a position of the particle on said semiconductor wafer prior to directing said gas cluster ion beam unto said particle.

6. A method for removing a particle from a semiconductor wafer, comprising:
providing a semiconductor wafer comprising a particle;
forming a gas cluster ion beam wherein said gas cluster ion beam comprises 50 to 5000 entities;
determining a position of the particle on said semiconductor wafer; and
directing said gas cluster ion beam unto said particle thereby removing said particle.

7. The method of claim 6 wherein said gas cluster ion beam is emitted from a GCIB tool at energies from 1 KeV to about 50 KeV.

8. The method of claim 7 wherein the entities comprising said gas cluster ion beam are selected from a group consisting of argon, CF₄, hydrogen, and nitrogen.

9. A method to remove copper CMP particles, comprising:
providing a semiconductor with a copper layer;
polishing said copper layer using chemical mechanical polishing;
forming a gas cluster ion beam; and
directing said gas cluster ion beam unto a particle on said copper layer thereby removing said particle.

10. The method of claim 9 wherein said gas cluster ion beam comprises 50 to 5000 entities.

11. The method of claim 10 wherein said gas cluster ion beam is emitted from a GCIB tool at energies from 1 KeV to about 50 KeV.

12. The method of claim 11 wherein the entities comprising said gas cluster ion beam are selected from a group consisting of argon, CF₄, hydrogen, and nitrogen.
